(19) United States
(12) Patent Application Publication
(10) Pub. No.: US 2006/0226122 A1
(43) Pub. Date: Oct. 12, 2006

(54) Selective wet etching of metal nitrides

(76) Inventors: William A. Wojtczak, Austin, TX (US); Dean DeWulf, Austin, TX (US)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 11/387,597

(22) Filed: Mar. 23, 2006

Related U.S. Application Data
(60) Provisional application No. 60/669,491, filed on Apr. 8, 2005.

(51) Int. Cl. C09K 13/00; B44C 1/22; H01L 21/461; C09K 13/04

(52) U.S. Cl. 216/83; 438/745; 252/79.1; 252/79.2; 252/79.4

(57) ABSTRACT

In one embodiment, the present invention relates to a wet etching composition including hydrogen peroxide; an organic onium hydroxide; and an acid. In another embodiment, the invention relates to a method of wet etching metal nitride selectively to surrounding structures comprising one or more of silicon, silicon oxides, glass, PSG, BPSG, BSG, silicon oxynitride, silicon nitride and silicon oxycarbide and combinations and mixtures thereof and/or photoresist materials, including steps of providing a wet etching composition including hydrogen peroxide, an organic onium hydroxide, and an organic acid; and exposing a metal nitride to be etched with the wet etching composition for a time and at a temperature effective to etch the metal nitride selectively to the surrounding structures.

### CROSS-REFERENCE TO RELATED APPLICATION

The present application claims benefit of and priority under 35 U.S.C. 119(e) to U.S. Provisional Application No. 60/669,491, filed 8 Apr. 2005, the entirety of which is hereby incorporated herein by reference.

### TECHNICAL FIELD

The present invention relates to wet etching of metal nitrides, such as titanium, tungsten, tantalum, hafnium and zirconium nitrides and mixtures thereof, selective to surrounding structures formed of, e.g., glass, BPSG, BSG, silicon dioxide, silicon nitride and photoresists.

### BACKGROUND

The lithography process generally consists of the following steps. A layer of photoresist (PR) material is first applied by a suitable process, such as spin-coating, onto the surface of the wafer. The PR layer is then selectively exposed to radiation such as ultraviolet light, electrons, or x-rays, with the exposed areas defined by the exposure tool, mask or computer data. After exposure, the PR layer is subjected to development which destroys unwanted areas of the PR layer, exposing the corresponding areas of the underlying layer. Depending on the resist type, the development stage may destroy either the exposed or unexposed areas. The areas with no resist material left on top of them are then subjected to additive or subtractive processes, allowing the selective deposition or removal of material on the substrate. For example, a material such as a metal nitride may be removed.

Etching is the process of removing regions of the underlying material that are no longer protected by the PR after development. The rate at which the etching process occurs is known as the etch rate. The etching process is said to be isotropic if it proceeds in all directions at the same rate. If it proceeds in only one direction, then it is anisotropic. Wet etching processes are generally isotropic.

An important consideration in any etching process is the ‘selectivity’ of the etchant. An etchant may not only attack the material being removed, but may also attack the mask or PR and/or the substrate (the surface under the material being etched) as well. The ‘selectivity’ of an etchant refers to its ability to remove only the material intended for etching, while leaving the mask and substrate materials intact.

Selectivity, S, is measured as the ratio between the different etch rates of the etchant for different materials. Thus, a good etchant needs to have a high selectivity value with respect to both the mask (Sfm) and the substrate (Sfs), i.e., its etching rate for the film being etched must be much higher than its etching rates for both the mask and the substrate.

Etching of metal nitrides, such as titanium nitride (TiN), has conventionally been carried out using either an aqueous mixture of ammonium hydroxide and hydrogen peroxide known as APM or SC-1, or a mixture of sulfuric acid and hydrogen peroxide known as SPM with varying etch selectivities relative to other materials. Typical APM solutions include, for example, a ratio of NH₄OH:H₂O₂:H₂O=1:1:5. Typical SPM solutions include, for example, a ratio of H₂SO₄:H₂O₂=1:5. Such formulations etch TiN and other metal nitrides but also swell and/or etch the PR as well as reduce the adhesion of the PR to the wafer surface, and may also tend to etch other surrounding structures.

A long-standing problem with using these standard, conventional wet etchants is their lack of selectivity. These wet etchants often attack surrounding structures, resulting in either etching or, particularly in the case of some photoresists, swelling and/or loss of adhesion to substrates to which the photoresist is applied. Such lack of selectivity becomes less and less acceptable as critical dimensions continue to be reduced.

Selective wet-etch solutions are important to device design and manufacturing for the most advanced semiconductor technologies. Such process chemicals are needed for both new device architecture and critical dimension reduction. Accordingly, a need exists, particularly in the semiconductor industry, for more selective wet etchants and methods of use thereof for removal of metal nitride selective to surrounding structures such as photoresists, silicon, glasses, silicon oxides, silicon nitrides and other materials.

### SUMMARY

In accordance with one embodiment of the present invention, there is provided a wet etching composition including hydrogen peroxide; an organic onium hydroxide; and an acid.

In accordance with another embodiment of the present invention, there is provided a method of wet etching metal nitride selectively to surrounding structures comprising one or more of silicon oxides, glass, PSG, BPSG, BSG, silicon oxynitride, silicon nitride and silicon oxycarbide and combinations and mixtures thereof, including steps of:

providing a wet etching composition including hydrogen peroxide, an organic onium hydroxide, and an acid; and

exposing a metal nitride to be etched with the wet etching composition for a time and at a temperature effective to etch the metal nitride selectively to the surrounding structures.

Thus, the present invention addresses the problem of providing selective wet etchants and methods of use thereof for selective removal of metal nitride selective to surrounding structures such as photoresists, glasses, both polycrystalline and monocrystalline silicon, silicon oxides, silicon nitrides and other materials.

### BRIEF DESCRIPTION OF THE DRAWINGS

FIG. 1 is a graph illustrating the selectivity of a wet etching composition in accordance with an embodiment of the present invention.

FIG. 2 is a graph illustrating changes in thickness as a function of the temperature of a wet etching composition in accordance with an embodiment of the present invention.

FIG. 3 is a graph illustrating lifetime loading of a wet etching composition in accordance with an embodiment of the present invention.

It should be appreciated that the process steps and structures described herein do not form a complete system or process flow for carrying out an etching process, such as would be used in manufacturing a semiconductor device or other device. The present invention can be practiced in conjunction with fabrication techniques and apparatus currently used in the art, and only so much of the commonly practiced materials, apparatus and process steps are included as are necessary for an understanding of the present invention.

### DETAILED DESCRIPTION

As used herein “composition” includes a mixture of the materials that comprise the composition as well as products formed by reactions between or decomposition of the materials that comprise the composition.

As is known in the art, although there is no direct relationship, in general in wet etching, as the etch rate increases, etch selectivity decreases. While it is important to obtain a high etch rate to maintain production rates, it is of equal or greater importance to obtain high selectivity. Thus, a balance of these two desirable properties needs to be struck. Accordingly, the present invention provides a wet etching composition having a good balance between etch rate and etch selectivity for metal nitrides relative to surrounding structures such as photoresists, glasses, both polycrystalline and monocrystalline silicon, silicon oxides, silicon nitrides and other materials.

Wet Etching Compositions

In accordance with one embodiment of the present invention, there is provided a wet etching composition including hydrogen peroxide; an organic onium hydroxide; and an acid.

Hydrogen Peroxide

Hydrogen peroxide is conventionally commercially available in concentrations ranging from 3% to 98%, and most often in concentrations of 30% to 50%, by volume. The concentration of the hydrogen peroxide in the compositions of the present invention may range from 0.1 vol % to about 20 vol % of the wet etching composition. Appropriate dilutions can be determined by those of skill in the art, based on the concentration supplied and the concentration desired to be employed in the wet etching composition. In one embodiment, the hydrogen peroxide concentration is in a range from about 3 vol. % to about 15 vol. %, and in another embodiment, the hydrogen peroxide concentration is in a range from about 5 vol. % to about 12 vol. %, and in another embodiment, the hydrogen peroxide concentration is in a range from about 7 vol. % to about 10 vol. %, and in one embodiment, the hydrogen peroxide concentration is about 8 vol. %, all concentrations based on the total volume of the wet etching solution.

Organic Onium Compounds

Useful organic onium compounds for the present invention include organic onium salts and organic onium hydroxides such as quaternary ammonium hydroxides, quaternary phosphonium hydroxides, tertiary sulfonium hydroxides, tertiary sulfoxonium hydroxides and imidazolium hydroxides. As used herein, disclosure of or reference to any onium hydroxide should be understood to include the corresponding salts, such as halides, carbonates, formates, sulfates and the like. As will be understood, such salts may be interchangeable with the hydroxides, depending on pH.

In one embodiment, the onium hydroxides may generally be characterized by the formula I:
A(OH)ₓ (I)
wherein A is an onium group and x is an integer equal to the valence of A. Examples of onium groups include ammonium groups, phosphonium groups, sulfonium, sulfoxonium and imidazolium groups. In one embodiment, the onium hydroxide should be sufficiently soluble in a solution such as water, alcohol or other organic liquid, or mixtures thereof to permit a useful wet etch rate.

In one embodiment, the quaternary ammonium hydroxides and quaternary phosphonium hydroxides may be characterized by the formula II: 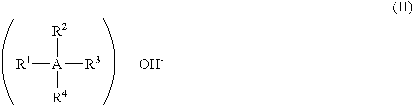
wherein A is a nitrogen or phosphorus atom, R¹, R², R³ and R⁴ are each independently alkyl groups containing from 1 to about 20, or 1 to about 10 carbon atoms, hydroxyalkyl or alkoxyalkyl groups containing from 2 to about 20, or 2 to about 10 carbon atoms, aryl groups or hydroxyaryl groups, or R¹ and R² together with A may form a heterocyclic group provided that if the heterocyclic group contains a C=A group, R³ is the second bond.

The alkyl groups R¹ to R⁴ may be linear or branched, and specific examples of alkyl groups containing from 1 to 20 carbon atoms include methyl, ethyl, propyl, butyl, pentyl, hexyl, heptyl, octyl, isooctyl, nonyl, decyl, isodecyl, dodecyl, tridecyl, isotridecyl, hexadecyl and octadecyl groups. R¹, R², R³ and R⁴ also may be hydroxyalkyl groups containing from 2 to 5 carbon atoms such as hydroxyethyl and the various isomers of hydroxypropyl, hydroxybutyl, hydroxypentyl, etc. In one embodiment, R¹, R², R³ and R⁴ are independently alkyl and/or hydroxyalkyl groups containing 1 to about 4 or 5 carbon atoms. Specific examples of alkoxyalkyl groups include ethoxyethyl, butoxymethyl, butoxybutyl, etc. Examples of various aryl and hydroxyaryl groups include phenyl, benzyl, and equivalent groups wherein benzene rings have been substituted with one or more hydroxy groups.

In one embodiment, the quaternary onium salts which can be employed in accordance with the present invention are characterized by the Formula III: 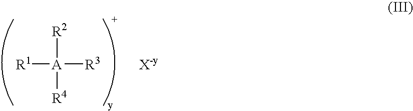
wherein A, R¹, R², R³ and R⁴ are as defined in Formula II, X⁻ is an anion of an acid, and y is a number equal to the valence of X. Examples of anions of acids include bicarbonates, halides, nitrates, formates, acetates, sulfates, carbonates, phosphates, etc.

In one embodiment, the quaternary ammonium compounds (hydroxides and salts) which can be used in accordance with the process of the present invention may be represented by Formula IV: 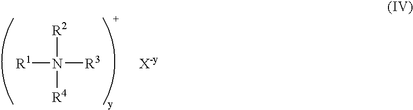
wherein R¹, R², R³, R⁴, and y are as defined in Formula II, and X⁻ is a hydroxide anion or an anion of an acid. In one embodiment, R¹-R⁴ are alkyl and/or hydroxyalkyl groups containing from 1 to about 4 or 5 carbon atoms. Specific examples of ammonium hydroxides include tetramethylammonium hydroxide (TMAH), tetraethylammonium hydroxide (TEAH), tetrapropylammonium hydroxide, tetrabutylammonium hydroxide, tetra-n-octylammonium hydroxide, methyltriethylammonium hydroxide, diethyldimethylammonium hydroxide, methyltripropylammonium hydroxide, methyltributylammonium hydroxide, cetyltrimethylammonium hydroxide, trimethylhydroxyethylammonium hydroxide, trimethylmethoxyethylammonium hydroxide, dimethyldihydroxyethylammonium hydroxide, methyltrihydroxyethylammonium hydroxide, phenyltrimethylammonium hydroxide, phenyltriethylammonium hydroxide, benzyltrimethylammonium hydroxide, benzyltriethylammonium hydroxide, dimethylpyrolidinium hydroxide, dimethylpiperidinium hydroxide, diisopropylimidazolinium hydroxide, N-alkylpyridinium hydroxide, etc. In one embodiment, the quaternary ammonium hydroxides used in accordance with this invention are TMAH and TEAH. The quaternary ammonium salts represented by Formula IV may be similar to the above quaternary ammonium hydroxides except that the hydroxide anion is replaced by, for example, a sulfate anion, a chloride anion, a carbonate anion, a formate anion, a phosphate ion, etc. For example, the salt may be tetramethylammonium chloride, tetramethylammonium sulfate (y=2), tetramethylammonium bromide, 1-methyl-2-butyl imidazolium hexafluorophosphate, n-butyl pyridinium hexafluorophosphate, etc.

Examples of quaternary phosphonium salts representative of Formula III wherein A=P which can be employed in accordance with the present invention include tetramethylphosphonium hydroxide, tetraethylphosphonium hydroxide, tetrapropylphosphonium hydroxide, tetrabutylphosphonium hydroxide, trimethylhydroxyethylphosphonium hydroxide, dimethyldihydroxyethylphosphonium hydroxide, tetradecyltributylphosphonium hydroxide, methyltrihydroxyethylphosphonium hydroxide, phenyltrimethylphosphonium hydroxide, phenyltriethylphosphonium hydroxide and benzyltrimethylphosphonium hydroxide, etc, and the corresponding anions, including, e.g., halides, sulfates, carbonates, and phosphates (including halophosphates as above, and other anions as disclosed herein).

In one embodiment, larger onium cations, including those with larger organic groups, provide more compatibility with photoresist materials. In one embodiment, smaller onium cations provide higher metal nitride etch rates. In one embodiment, asymmetric onium cations, such as benzyltrimethylammonium, provide a good balance between photoresist compatibility and acceptable metal nitride etch rate. Thus, in one embodiment, the organic onium hydroxide comprises an asymmetric onium cation, in which one or more of the organic groups contain, on average, at least about four carbon atoms, in one embodiment, at least about six carbon atoms, and in another embodiment, at least about 8 carbon atoms.

In another embodiment, the tertiary sulfonium hydroxides and salts which can be employed in accordance with the present invention may be represented by the formula V: 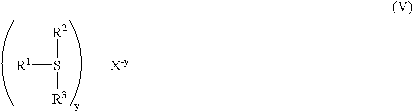
wherein R¹, R² and R³, X⁻ and y are as defined in Formula III.

Examples of the tertiary sulfonium compounds represented by Formula V include trimethylsulfonium hydroxide, triethylsulfonium hydroxide, tripropylsulfonium hydroxide, etc, and the corresponding salts such as the halides, sulfates, nitrates, carbonates, etc.

In another embodiment, the tertiary sulfoxonium hydroxides and salts which can be employed in accordance with the present invention may be represented by the formula VI: 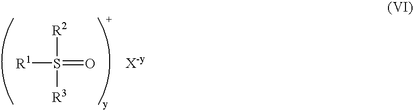
wherein R¹, R² and R³, X⁻ and y are as defined in Formula III.

Examples of the tertiary sulfoxonium compounds represented by Formula V include trimethylsulfoxonium hydroxide, triethylsulfoxonium hydroxide, tripropylsulfoxonium hydroxide, etc, and the corresponding salts such as the halides, sulfates, nitrates, carbonates, etc.

In another embodiment, the imidazolium hydroxides and salts which can be employed in accordance with the present invention may be represented by the formula VII: 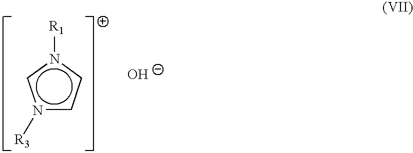
wherein R¹ and R³ are as defined in Formula II, and X⁻ is an anion of an acid. As will be understood, in formula (VII) and in the foregoing formulae (I)-(VI), if X⁻ is an anion of a dibasic acid, such as SO₄⁻², the stoichiometry will be adjusted accordingly, for example, for the dibasic acid anion, instead of 2X⁻, there would be only one X⁻, and if X⁻ is an anion of a tribasic acid, such as PO₄⁻³ a corresponding stoichiometric adjustment would be made.

Onium hydroxides are commercially available. Additionally, onium hydroxides can be prepared from the corresponding onium salts such as the corresponding onium halides, carbonates, formates, sulfates and the like. Various methods of preparation are described in U.S. Pat. No. 4,917,781 (Sharifian et al) and U.S. Pat. No. 5,286,354 (Bard et al) which are hereby incorporated by reference. There is no particular limit as to how the onium hydroxide is obtained or prepared.

In one embodiment, the organic onium hydroxide comprises one or more of tetramethylammonium hydroxide, tetraethylammonium hydroxide, tetrapropylammonium hydroxide, tetrabutylammonium hydroxide, methyltriphenylammonium hydroxide, phenyltrimethylammonium hydroxide, benzyltrimethylammonium hydroxide, methyltriethanolammonium hydroxide, tetrabutylphosphonium hydroxide, methyltriphenylphosphonium hydroxide, trihexyltetradecylphosphonium hydroxide, tributyltetradecylphosphonium hydroxide, [(CH₃)₃NCH₂CH(OH)CH₂N(CH₃)₃]²⁺[OH⁻]₂, 1-butyl-3-methylimidazolium hydroxide, trimethylsulfonium hydroxide, trimethylsulfoxonium hydroxide, trimethyl (2,3-dihydroxypropyl) ammonium hydroxide, [(C₆H₅)CH₂N(CH₃)₂CH₂CH(OH)CH₂N(CH₃)₂CH₂CH(OH)CH₂N(CH₃)₂CH₂—CH(OH)CH₂N(CH₃)₂CH₂(C₆H₅)]⁴⁺[OH⁻]₄, and [(CH₃)₃NCH₂CH(OH)CH₂OH]⁺[OH⁻], and hexamethonium dihydroxide. In one embodiment, the onium hydroxide is benzyltrimethylammonium hydroxide.

The concentration of the onium hydroxide in the compositions of the present invention may range from 0.1 wt % to about 20 wt % of the wet etching composition. Appropriate dilutions can be determined by those of skill in the art, based on the concentration supplied and the concentration desired to be employed in the wet etching composition. In one embodiment, the onium hydroxide concentration is in a range from about 0.5 wt % to about 15 wt %, and in another embodiment, the onium hydroxide concentration is in a range from about 2 wt % to about 10 wt %, and in another embodiment, the onium hydroxide concentration is in a range from about 3 wt % to about 8 wt %, and in one embodiment, the onium hydroxide concentration is about 4 wt %, all concentrations based on the total weight of the wet etching solution.

Acids

Any suitable acid may be used. In one embodiment, the acid is an organic acid. In another embodiment, the acid is an inorganic acid. The acid may include a mixture or combination of two or more these acids.

In one embodiment, the acid is other than a bi- or higher dentate chelating agent. In one embodiment, the acid is other than ethylene diamine tetraacetic acid (EDTA) or similar chelating agents based on ethylene diamine, diethylene triamine and higher multi-amine multi-acetic acid compounds.

Typical examples of the organic acids may include formic acid, acetic acid, propionic acid, butyric acid, isobutyric acid, valeric acid, ethylmethylacetic acid, trimethylacetic acid, glycolic acid, butanetetracarboxylic acid, oxalic acid, succinic acid, malonic acid, citric acid, tartaric acid, malic acid, gallic acid, behenic acid, arachidic acid, stearic acid, palmitic acid, lauric acid, salicylic acid, benzoic acid, and 3,5-dihydroxybenzoic acid, or the like. Mixtures of two or more of these acids may be used.

In one embodiment, the organic acid comprises citric acid. In one embodiment, hydroxycarboxylic acids, such as citric acid, appear to stabilize alkaline peroxide compositions, extending the bath life.

Inorganic acids may include phosphonic, phosphinic, phosphoric, or phosphorous acids.

The acid may include, for example, nitrilotrimethylene phosphonic acid, hydroxyethylidene diphosphonic acid, phenylphosphonic acid, methylphosphonic acid, phenylphosphinic acid, and similar acids based on the phosphonic, phosphinic, phosphoric, or phosphorous acids.

Organic sulfonic acids, including alkyl, aryl, aralkyl and alkaryl sulfonic acids, in which the alkyl substituents may range from C₁ to about C₂₀ and in which the aryl substituents (before substitution) may be phenyl or naphthyl or higher, or mixtures of two or more of these, may be suitably used as the acid component. Alkyl sulfonic acids include, e.g., methane sulfonic acid. Aryl sulfonic acids include, e.g., benzene sulfonic acid. Aralkyl sulfonic acids include, e.g., benzyl sulfonic acid. Alkaryl sulfonic acids include, e.g., toluene sulfonic acid.

Exemplary inorganic and organic acids that may be included in the compositions include hydrochloric acid, nitric acid, sulfuric acid, sulfurous acid, hydrobromic acid, perchloric acid, fluoboric acid, phytic acid, phosphorous acid, hydroxyethylidene diphosphonic acid, nitrilotrimethylene phosphonic acid, methylphosphonic acid, phenylphosphonic acid, phenylphosphinic acid, N-(2-hydroxyethyl)-N′-(2-ethane sulfonic acid) (HEPES), 3-(N-morpholino) propane sulfonic acid (MOPS), piperazine-N,N′-bis(2-ethane sulfonic acid) (PIPES), methanesulfonic acid, ethane disulfonic acid, toluene sulfonic acid, nitrilotriacetic acid, maleic acid, phthalic acid, lactic acid, ascorbic acid, gallic acid, sulfoacetic acid, 2-sulfobenzoic acid, sulfanilic acid, phenylacetic acid, betaine, crotonic acid, levulinic acid, pyruvic acid, trifluoroacetic acid, glycine, cyclohexanecarboxylic acid, cyclohexanedicarboxylic acid, cyclopentanedicarboxylic acid, adipic acid, and mixtures or combinations of two or more thereof.

The concentration of the acid in the compositions of the present invention may range from 0.1 wt % to about 10 wt % of the wet etching composition. Appropriate dilutions can be determined by those of skill in the art, based on the concentration supplied and the concentration desired to be employed in the wet etching composition. In one embodiment, the acid concentration is in a range from about 0.2 wt % to about 5 wt %, and in another embodiment, the acid concentration is in a range from about 0.5 wt % to about 4 wt %, and in another embodiment, the acid concentration is in a range from about 1 wt % to about 3 wt %, and in one embodiment, the acid concentration is about 2 wt %, all concentrations based on the total weight of the wet etching solution. The concentration of the acid may be adjusted based on factors such as the strength (or pKₐ), solubility and complexing power of the acid.

Wet Etching Composition pH

The pH of the wet etching composition in accordance with the present invention may be a pH in the range from about 5 to about 10, and in one embodiment, a pH in the range from about 6 to about 9.5, and in another embodiment, a pH in the range from about 7 to about 9, and in one embodiment, the pH is about 9. The pH can be adjusted as needed by manipulating acid selection, acid concentration, onium hydroxide concentration and by addition of suitable buffers, if required, as will be understood by those of skill in the art.

Photoresists

The present invention may be used with a variety of different photoresist materials, including but not limited to, Novolacs, methacrylates, acrylates, styrenes, sulfones and isoprenes. Exemplary photoresist materials include positive photoresists, such as those that include a Novolac resin, a diazonaphthaquinone, and a solvent (e.g., n-butyl alcohol or xylene), and negative photoresist materials, such as those that include a cyclized synthetic rubber resin, bis-arylazide, and an aromatic solvent. In one embodiment, suitable photoresists include negative photoresists, such as for example, MacDermid Aquamer CFI or MI, du Pont Riston 9000, or du Pont Riston 4700, or Shipley UV5 and TOK DP019. Positive photoresists include AZ3312, AZ3330, Shipley 1.2 L and Shipley 1.8M. Negative photoresists include nLOF 2020 and SU8. Examples of additional suitable resists include the AZ 5218, AZ 1370, AZ 1375, or AZ P4400, from Hoechst Celanese; CAMP 6, from OCG; DX 46, from Hoechst Celanese; XP 8843, from Shipley; and JSR/NFR-016-D2, from JSR, Japan. Suitable photoresists are described in U.S. Pat. Nos. 4,692,398; 4,835,086; 4,863,827 and 4,892,801. Suitable photoresists may be purchased commercially as AZ-4620, from Clariant Corporation of Somerville, N.J. Other suitable photoresists include solutions of polymethylmethacrylate (PMMA), such as a liquid photoresist available as 496 k PMMA, from OLIN HUNT/OCG, West Paterson, N.J. 07424, comprising polymethylmethacrylate with molecular weight of 496,000 dissolved in chlorobenzene (9 wt %); (meth)acrylic copolymers such as P(MMA-MM) (poly methyl methacrylate-methacrylic acid); PMMA/P(MMA-MM) polymethylmethacrylate/(poly methyl methacrylate-methacrylic acid). Any suitable photoresist, whether existing or yet-to-be-developed, is contemplated, regardless of whether such comprises a positive or negative type photoresist.

Methods of Wet Etching Metal Nitrides

In accordance with another embodiment of the present invention, there is provided a method of wet etching a metal nitride selectively to surrounding structures comprising one or more of silicon oxides, glass, phosphosilicate glass (PSG), borophosphosilicate glass (BPSG), borosilicate glass (BSG), silicon oxynitride, silicon nitride and silicon oxycarbide, or combinations or mixtures thereof, including steps of:

providing a wet etching composition including hydrogen peroxide, an organic onium hydroxide, and an organic acid; and

exposing a metal nitride to be etched with the wet etching composition for a time and at a temperature effective to etch the metal nitride selectively to the surrounding structures. The following describes exemplary conditions for carrying out embodiments of this method. Additional details and modifications can be determined by those of skill in the art.

Processing Time

The time needed for carrying out a method of wet etching a metal nitride in accordance with an embodiment of the present invention may be suitably selected based on factors known to those of skill in the art, including the identity of the metal nitride to be etched, the thickness of the metal nitride to be etched, the method by which the metal nitride was deposited (which may affect properties such as hardness, porosity and texture of the metal nitride), concentrations of peroxide, onium hydroxide and organic acid, temperature and rate of stirring or mixing of the wet etching composition, volume of the wet etching composition relative to the quantity and/or size of wafers or parts to be treated, and similar factors known to affect etch rates in conventional metal nitride etching methods. In one embodiment, the time of exposure of the wet etching composition to the metal nitride ranges from about 1 minute to about 60 minutes, and in another embodiment, the time ranges from about 2 minutes to about 40 minutes, and in another embodiment the time ranges from about 5 minutes to about 20 minutes, and in yet another embodiment, the time ranges from about 7 to about 15 minutes. In one embodiment, the time ranges from about 30 seconds to about 4 minutes.

Processing Temperatures

The bath or solution temperature for carrying out a method of wet etching a metal nitride in accordance with an embodiment of the present invention may be suitably selected based on factors known to those of skill in the art, including the identity of the metal nitride to be etched, the thickness of the metal nitride to be etched, the method by which the metal nitride was deposited (which may affect properties such as hardness, porosity and texture of the metal nitride), concentrations of peroxide, onium hydroxide and organic acid, rate of stirring or mixing of the wet etching composition, volume of the wet etching composition relative to the quantity and/or size of wafers or parts to be treated, the time allotted for the etching, and similar factors known to affect etch rates in conventional metal nitride etching methods. In one embodiment, the bath or solution temperature of the wet etching composition for wet etching the metal nitride ranges from about 20° C. to about 60° C., and in another embodiment, the bath or solution temperature ranges from about 30° C. to about 60° C., and in another embodiment the bath or solution temperature ranges from about 35° C. to about 50° C., and in yet another embodiment, the bath or solution temperature ranges from about 40° C. to about 45° C.

Etch Rates

Etch rates may be suitably selected by those of skill in the art based on factors known, such as time, temperature, identity of the organic acid, of the organic onium hydroxide and of the metal nitride to be etched, and on the selectivity attained for the specific materials surrounding the metal nitride to be etched, and other factors known or easily determined by persons of skill in the art.

In one embodiment, the etch rate for the metal nitride ranges from about 5 to about 200 angstroms (Å) per minute (Å/min), and in another embodiment, the etch rate for the metal nitride ranges from about 10 to about 100 Å/min, and in another embodiment, the etch rate for the metal nitride ranges from about 20 to about 70 Å/min, and in another embodiment, the etch rate for the metal nitride ranges from about 30 to about 50 Å/min.

In one embodiment, the etch rate for titanium nitride (TiN) ranges from about 20 to about 70 Å/min, and in another embodiment, the etch rate for TiN ranges from about 30 to about 50 Å/min.

In one embodiment, the etch rate for tungsten nitride ranges from about 5 to about 50 Å/min, and in one embodiment, from about 10 to about 40 Å/min.

In one embodiment, the etch rate for tantalum nitride ranges from about 2 to about 30 Å/min, and in one embodiment, from about 5 to about 25 Å/min.

In one embodiment, the etch rate for hafnium nitride ranges from about 2 to about 30 Å/min, and in one embodiment, from about 5 to about 25 Å/min.

In one embodiment, the etch rate for zirconium nitride ranges from about 2 to about 30 Å/min, and in one embodiment, from about 5 to about 25 Å/min.

Selectivity

In one embodiment, the selectivity obtained by using the wet etching composition in accordance with the present invention as described in the process herein, ranges from about 2:1 to about 200:1. As is known in the art, the higher the selectivity, the better. In one embodiment, the selectivity ranges from about 10:1 to about 180:1, and in another embodiment, from about 20:1 to about 65:1. As is known, selectivity varies with the materials, so the selectivity is often expressed with respect to the two or more materials being compared. That is, the selectivity of an etchant for a metal nitride, e.g., TiN, relative to surrounding materials, such as photoresist or other materials, such as silicon oxides, is the important selectivity measure. Thus, each of the foregoing selectivities may be for a metal nitride relative to one or more of a photoresist, a glass, a silicon oxide, a silicon nitride, a silicon oxynitride, or other surrounding materials. The selectivity may be measured by comparing relative etch rates of each material, or by comparing etch rate of the target material to another measure, such as swelling of a photoresist.

In one embodiment, the present invention provides a selectivity for removal of titanium nitride relative to photoresist swelling, where both etch rate and swelling rate are measured as change in thickness in angstroms (Å) per minute (Å/min), and may range from 2:1 to about 200:1. In one embodiment, the selectivity for removal of titanium nitride relative to photoresist swelling ranges from about 10:1 to about 180:1, and in another embodiment, for removal of titanium nitride relative to photoresist swelling from about 20:1 to about 65:1.

In one embodiment, after etching a metal nitride having a thickness in the range from about 200-300 Å at an etch rate of about 30-50 Å/min, the photoresist swelling is less than about 5% of the initial thickness, in another embodiment, under these conditions, the photoresist swelling is less than about 4% of the initial thickness, in another embodiment, under these conditions, the photoresist swelling is less than about 3% of the initial thickness, in another embodiment, under these conditions, the photoresist swelling is less than about 2% of the initial thickness, in another embodiment, under these conditions, the photoresist swelling is less than about 1% of the initial thickness.

Exemplary Experimental Procedure:

The following is an exemplary process for carrying out an embodiment of the present invention, and is provided for exemplary, non-limiting purposes.

Film Type

10000-15000 Å BPSG on Silicon

200-300 Å TiN on 1000 Å SiO₂

10000-15000 Å Soft Baked Novolac Photoresist on Silicon

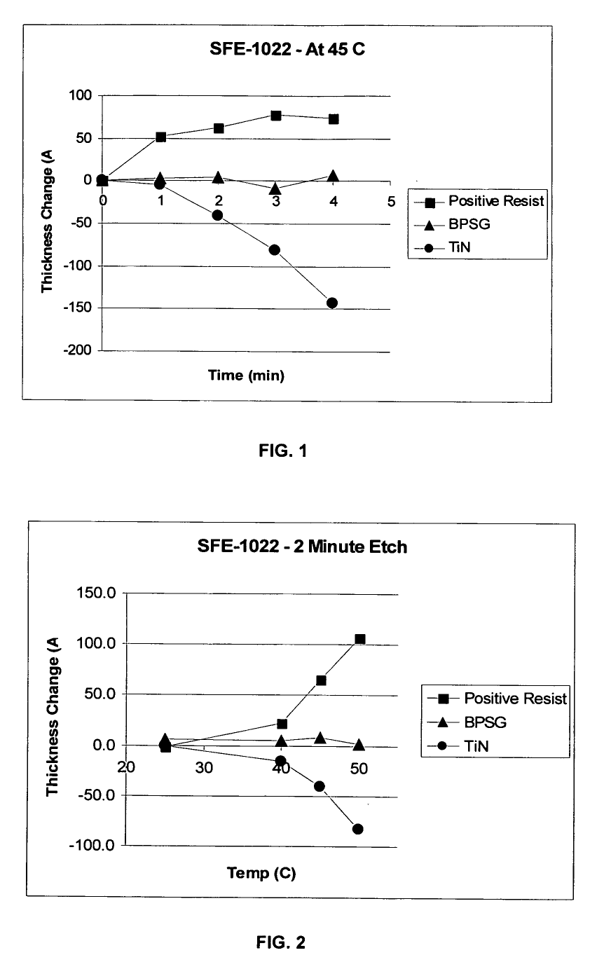

TiN, BPSG and photoresist wafers are cleaved into 1″×1″ square pieces. The pieces are submerged into the etchant solutions in plastic beakers at 25-50° C. The wafer pieces are processed for 1-4 min after which they are rinsed with DI water and blown dry with nitrogen. The film thicknesses before and after processing are determined by reflectometry for the photoresist and BPSG wafer pieces using a NANOSPEC 210 and by resistance for TiN using a Tencor RS35c. The films are also examined by optical microscopy to assess uniformity of etch for TiN and adhesion for the resist wafer pieces. The conditions for bath life tests are as follows: bath temperature of 45° C., 408 g sample, open cup (approximately a 9:7 aspect ratio vessel) with slow stirring and ventilation. TiN loading of the bath life sample may be accomplished by processing wafer pieces with known surface area in 408 g of etchant to remove 80 Å of TiN (ca. 3-4 min process) every 2 hours for a total of 8 hours. Etch tests on TiN, BPSG and resist may be performed periodically during the experiment. The TiN-loading factor in FIG. 1, in ppm, represents the amount of TiN loaded (dissolved) for one formulation, SFE-1022, assuming a TiN film density of 5.2 g/cm³. Assuming 80 Å TiN removed where the TiN covers 25% of the surface of a 200 mm wafer, each loading cycle in the bath loading test (in TiN removed, ppm) is equivalent to 25 (200 mm) wafers processed in an 8 gallon immersion tank.

Results:

The results for etch rate and selectivity for TiN, BPSG and photoresist for various formulations are presented in Tables 1a & 1b.

TABLE 1a
Processed at 50° C. for 2-36 min

| | | | Etch or | | |
|---|---|---|---|---|---|
| | | Processing | Swelling | | |
| Formulation #/ | | Temp. (° C.)/ | Rate | Selectivity | Chemical |
| Composition | Film | Time (min) | (Å/min) | TiN:photoresist | Properties |
| SFE-981 | TiN | 50/2 | −3.3 | | Aqueous |
| 8% H₂O₂ | Photoresist | 50/36 | −1.5 | 2.2:1 | Peroxide |
| 2% Citric Acid | | | | | pH = 3.0 |
| 1.9% TMAH | | | | | |
| SFE-982 | TiN | 50/2 | −16.3 | | Aqueous |
| 8% H₂O₂ | Photoresist | 50/36 | −1.8 | 9:1 | Peroxide |
| 2% Citric Acid | | | | | pH = 7.0 |
| 2.1% TMAH | | | | | |
| SFE-983 | TiN | 50/2 | −37.7 | | Aqueous |
| 8% H₂O₂ | Photoresist | 50/36 | −0.6 | 63:1 | Peroxide |
| 2% Citric Acid | | | | | pH = 9.0 |
| 2.2% TMAH | | | | | |
| SFE-1018 | TiN | 50/2 | −10.9 | | Aqueous |
| 8% H₂O₂ | Photoresist | 50/25 | −0.2 | 55:1 | Peroxide |
| 2% Citric Acid | | | | | pH = 9.0 |
| TBAH | | | | | |
| SFE-1019 | TiN | 50/2 | −18.7 | | Aqueous |
| 8% H₂O₂ | Photoresist | 50/25 | −0.1 | 181:1 | Peroxide |
| 2% Citric Acid | | | | | pH = 9.0 |
| Tetrabutyl | | | | | |
| phosphonium | | | | | |
| hydroxide | | | | | |
| SFE-1021 | TiN | 50/2 | −8.1 | | Aqueous |
| 8% H₂O₂ | Photoresist | 50/25 | +13.1* | 0.6:1 | Peroxide |
| 1% Citric Acid | | | | | pH = 9.0 |
| 3.67% dodecyl | | | | | |
| trimethyl | | | | | |
| ammonium | | | | | |
| hydroxide | | | | | |
| SFE-1022 | TiN | 50/2 | −49.1 | | Aqueous |
| 8% H₂O₂ | Photoresist | 50/32 | +0.8* | 61:1 | Peroxide |
| 1% Citric Acid | | | | | pH = 9.0 |
| 3.67% Benzyl | | | | | |
| trimethyl | | | | | |
| ammonium | | | | | |
| hydroxide | | | | | |

*positive sign indicates swelling of film

TABLE 1b
SFE-1022 Processed at 25-50° C. for 2 min

| | | | Etch/Swell | Thickness |
|---|---|---|---|---|
| | | Proc. Temp. (C.)/ | Rate | Change |
| Formulation # | Film | Proc. Time (min) | (Å/min)* | (Å)* |
| SFE-1022 | TiN | 25/2 | −0.03 | −0.06 |
| | BPSG | | +2.9 | +5.8 |
| | Photoresist | | +0.75 | −1.5 |
| | TiN | 40/2 | −7.6 | −15.2 |
| | BPSG | | +2.4 | +4.8 |
| | Photoresist | | +11.4 | +22.8 |
| | TiN | 45/2 | −20.2 | −40.4 |
| | BPSG | | +3.9 | +7.8 |
| | Photoresist | | +33 | +66 |
| | TiN | 50/2 | −41.3 | −82.6 |
| | BPSG | | +1.2 | +2.3 |
| | Photoresist | | +53.6 | +107.2 |

*positive sign indicates swelling of film, negative sign indicates etching of film

TABLE 2
SFE-1022 Processed at 45° C. for 1-4 min

| | | | Etch/Swell | Thickness |
|---|---|---|---|---|
| | | Proc. Temp. (C.)/ | Rate | Change |
| Formulation # | Film | Proc. Time (min) | (Å/min)* | (Å)* |
| SFE-1022 | TiN | 45/1 | −5.1 | −5.1 |
| | BPSG | | +3.5 | +3.5 |
| | Photoresist | | +52 | +52 |
| | TiN | 45/2 | −20.5 | −41 |
| | BPSG | | +2.4 | +4.8 |
| | Photoresist | | +31 | +62 |
| | TiN | 45/3 | −27 | −80.9 |
| | BPSG | | −2.7 | −8 |
| | Photoresist | | +26 | +78 |
| | TiN | 45/4 | −35.9 | −143.6 |
| | BPSG | | +1.7 | +6.8 |
| | Photoresist | | +18.5 | +74 |

*positive sign indicates swelling of film, negative sign indicates etching of film

Discussion:

As shown by the foregoing examples, formulations exhibit a desirable performance criteria for a TiN etchant, namely, a TiN etch rate of 30-50 Å/min and high TiN:resist selectivity (as measured as TiN etch to resist thickness change). High selectivity to BPSG oxide is also desirable. SFE-1022 is an aqueous peroxide chemistry operated, in one embodiment, at −50° C.

FIG. 1 is a graph for etching in the wet etching composition of example SFE-1022 of a sample including TiN, BPSG, and photoresist, showing resist thickness change vs. time (min) at 45° C. (a negative sign indicates etch, positive sign indicates swelling). As shown in FIG. 1 for SFE-1022, the thickness change of TiN increases with dip time. If the targeted removal amount of TiN is 80 Å, the dip time using SFE-1022 would be about 3-4 minutes at 45° C. As shown in FIG. 1, the photoresist swells by less than about 1% of its starting thickness within the first 3 minutes of exposure to SFE-1022. For comparison, the resist when dipped in deionized water shows a similar swelling behavior to that observed for the SFE-1022 immersion test. In neither case does the resist delaminate or change in appearance (viewed by optical microscopy) after exposure to the SFE-1022 solution. Although not to be bound by theory, it is considered likely that the slight swelling observed for immersion in SFE-1022 and water over short time periods of 1-10 minutes does not indicate a major chemical change in the resist but rather a small interaction or surface solvation by the contacting liquid. This is in contrast to conventional ammonium hydroxide/peroxide (e.g., APM or SC-1) TiN etchants, which exhibit more extensive chemical attack on the resist.

The thickness change of the resist and the TiN as a function of composition temperature for example SFE-1022 is presented in FIG. 2. As shown in FIG. 2, both the removed amount of TiN increases and the swelling of the resist increases slightly, as the temperature increases. The resist swelling is still <1% of the resist thickness in the operating temperature range of 40-50° C.

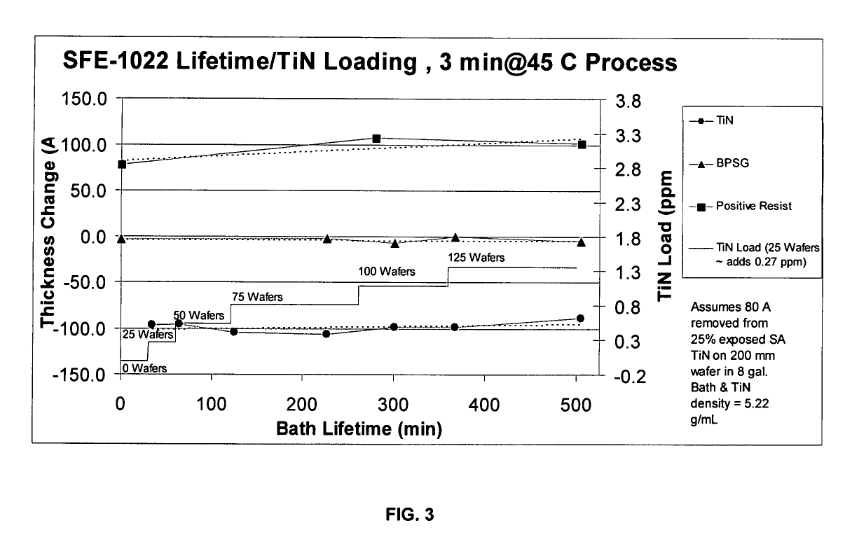

FIG. 3 illustrates a TiN loading test for example SFE-1022, showing thickness change versus time (min) and TiN load (ppm). FIG. 3 is based on bath life tests on SFE-1022 to assess bath stability. The conditions are: bath temperature of 45° C., 408 g sample, open cup (approximately 9:7 aspect ratio vessel) with slow stirring and ventilation. TiN loading of the bath life sample is accomplished by processing wafer pieces with surface area of 9.5e16 Å² in 408 g of etchant to remove a thickness of 220 Å TiN (0.27 ppm TiN load per cycle assuming TiN density of 5.22 g/cm³). Etch tests on TiN, BPSG and resist are performed periodically during the experiment at conditions of 45° C. @ 3 min. The loading test assumes 80 Å TiN is removed over 25% of the surface of a 200 mm wafer. As a result, each loading cycle in the bath-loading test (in TiN removed, ppm) is roughly equivalent to 25 (200 mm) wafers processed in an 8 gallon immersion tank. The data in FIG. 3 indicate that the SFE-1022 performance, in terms of TiN, BPSG, and resist thickness change over time, is not substantially affected by TiN loading or bath age.

Any numerical values recited herein include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, in one embodiment from 20 to 80, in another embodiment from 30 to 70, it is intended that values such as 15 to 85, 22 to 68, 43 to 51, 30 to 32 and the like, are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly stated in this application in a similar manner.

While the invention has been explained in relation to certain of its exemplary embodiments, it is to be understood that various modifications thereof will become apparent to those skilled in the art upon reading the specification. Therefore, it is to be understood that the invention disclosed herein is intended to cover such modifications as fall within the scope of the appended claims.

What is claimed is:

1. A wet etching composition comprising:
hydrogen peroxide;
an organic onium hydroxide; and
an acid.

2. The composition of claim 1 wherein the acid is an organic acid or an inorganic acid, or mixture of two or more thereof.

3. The composition of claim 1 wherein the organic onium hydroxide is other than TMAH.

4. The composition of claim 1 wherein the organic onium hydroxide comprises one or more of an ammonium, phosphonium, sulfonium, sulfoxonium, or imidazolium hydroxide.

5. The composition of claim 1 wherein the acid comprises formic acid, acetic acid, propionic acid, butyric acid, isobutyric acid, valeric acid, ethylmethylacetic acid, trimethylacetic acid, citric acid, glycolic acid, butanetetracarboxylic acid, oxalic acid, succinic acid, malonic acid, citric acid, tartaric acid, malic acid, gallic acid, behenic acid, arachidic acid, stearic acid, palmitic acid, lauric acid, salicylic acid, benzoic acid, and 3,5-dihydroxybenzoic acid, or a mixture of any two or more thereof.

6. The composition of claim 1 wherein the acid comprises phosphonic acid, phosphinic acid, phosphoric acid, or phosphorous acid or a mixture of any two or more thereof.

7. The composition of claim 1 wherein the acid comprises nitrilotrimethylene phosphonic acid, hydroxyethylidene diphosphonic acid, phenylphosphonic acid, methylphosphonic acid, phenylphosphinic acid or a mixture of any two or more thereof.

8. The composition of claim 1 wherein the acid comprises an organic sulfonic acid.

9. The composition of claim 1 wherein the acid comprises hydrochloric acid, nitric acid, sulfuric acid, sulfurous acid, hydrobromic acid, perchloric acid, fluoboric acid, phytic acid, phosphorous acid, hydroxyethylidene diphosphonic acid, nitrilotrimethylene phosphonic acid, methylphosphonic acid, phenylphosphonic acid, phenylphosphinic acid, N-(2-hydroxyethyl)-N′-(2-ethane sulfonic acid) (HEPES), 3-(N-morpholino) propane sulfonic acid (MOPS), piperazine-N,N′-bis(2-ethane sulfonic acid) (PIPES), methanesulfonic acid, ethane disulfonic acid, toluene sulfonic acid, nitrilotriacetic acid, maleic acid, phthalic acid, lactic acid, ascorbic acid, gallic acid, sulfoacetic acid, 2-sulfobenzoic acid, sulfanilic acid, phenylacetic acid, betaine, crotonic acid, levulinic acid, pyruvic acid, trifluoroacetic acid, glycine, cyclohexanecarboxylic acid, cyclohexanedicarboxylic acid, cyclopentanedicarboxylic acid, adipic acid, and mixtures or combinations of two or more thereof.

10. The composition of claim 1 wherein the composition is selective for etching metal nitride over one or more of silicon, silicon oxides, glass, PSG, BPSG, BSG, silicon oxynitride, silicon nitride and silicon oxycarbide.

11. The composition of claim 1 wherein the composition is selective for etching metal nitride with respect to swelling of photoresist materials.

12. The composition of claim 1 wherein the organic onium hydroxide comprises one or more of tetramethylammonium hydroxide, tetraethylammonium hydroxide, tetrapropylammonium hydroxide, tetrabutylammonium hydroxide, methyltriphenylammonium hydroxide, phenyltrimethylammonium hydroxide, benzyltrimethylammonium hydroxide, methyltriethanolammonium hydroxide, tetrabutylphosphonium hydroxide, methyltriphenylphosphonium hydroxide, trihexyltetradecylphosphonium hydroxide, tributyltetradecylphosphonium hydroxide, [(CH₃)₃NCH₂CH(OH)CH₂N(CH₃)₃]²⁺[OH⁻]₂, 1-butyl-3-methylimidazolium Hydroxide, trimethylsulfonium hydroxide, trimethylsulfoxonium hydroxide, trimethyl (2,3-dihydroxypropyl) ammonium hydroxide, [(C₆H₅)CH₂N(CH₃)₂CH₂CH(OH)CH₂N(CH₃)₂CH₂CH(OH)CH₂N(CH₃)₂CH₂CH(OH)CH₂N(CH₃)₂CH₂(C₆H₅)]⁴⁺[OH⁻]₄, and [(CH₃)₃NCH₂CH(OH)CH₂OH]⁺[OH⁻], hexamethonium dihydroxide.

13. The composition of claim 1 wherein the metal nitride comprises a nitride of titanium, tungsten, tantalum, hafnium, zirconium or mixtures or nitrides of alloys thereof.

14. A method of wet etching metal nitride selectively to surrounding structures comprising one or more of silicon, silicon oxides, glass, PSG, BPSG, BSG, silicon oxynitride, silicon nitride and silicon oxycarbide, or combinations or mixtures thereof and/or photoresist materials, comprising:
providing a wet etching composition comprising:
hydrogen peroxide,
an organic onium hydroxide, and
an acid;
exposing a metal nitride to be etched with the wet etching composition for a time and at a temperature effective to etch the metal nitride selectively to the surrounding structures.

15. The method of claim 14 wherein the acid is an organic acid or an inorganic acid, or mixture of two or more thereof.

16. The method of claim 14 wherein the organic onium hydroxide is other than TMAH.

17. The method of claim 14 wherein the organic onium hydroxide comprises one or more of an ammonium, phosphonium, sulfonium, sulfoxonium, or imidazolium hydroxide.

18. The method of claim 14 wherein the acid comprises one or more of formic acid, acetic acid, propionic acid, butyric acid, isobutyric acid, valeric acid, ethylmethylacetic acid, trimethylacetic acid, citric acid, glycolic acid, butanetetracarboxylic acid, oxalic acid, succinic acid, malonic acid, citric acid, tartaric acid, malic acid, gallic acid, behenic acid, arachidic acid, stearic acid, palmitic acid, lauric acid, salicylic acid, benzoic acid, and 3,5-dihydroxybenzoic acid.

19. The method of claim 14 wherein the acid comprises phosphonic acid, phosphinic acid, phosphoric acid, or phosphorous acid or a mixture of any two or more thereof.

20. The method of claim 14 wherein the acid comprises nitrilotrimethylene phosphonic acid, hydroxyethylidene diphosphonic acid, phenylphosphonic acid, methylphosphonic acid, phenylphosphinic acid or a mixture of any two or more thereof.

21. The method of claim 14 wherein the acid comprises an organic sulfonic acid.

22. The method of claim 14 wherein the acid comprises hydrochloric acid, nitric acid, sulfuric acid, sulfurous acid, hydrobromic acid, perchloric acid, fluoboric acid, phytic acid, phosphorous acid, hydroxyethylidene diphosphonic acid, nitrilotrimethylene phosphonic acid, methylphosphonic acid, phenylphosphonic acid, phenylphosphinic acid, N-(2-hydroxyethyl)-N′-(2-ethane sulfonic acid) (HEPES), 3-(N-morpholino) propane sulfonic acid (MOPS), piperazine-N,N′-bis(2-ethane sulfonic acid) (PIPES), methanesulfonic acid, ethane disulfonic acid, toluene sulfonic acid, nitrilotriacetic acid, maleic acid, phthalic acid, lactic acid, ascorbic acid, gallic acid, sulfoacetic acid, 2-sulfobenzoic acid, sulfanilic acid, phenylacetic acid, betaine, crotonic acid, levulinic acid, pyruvic acid, trifluoroacetic acid, glycine, cyclohexanecarboxylic acid, cyclohexanedicarboxylic acid, cyclopentanedicarboxylic acid, adipic acid, and mixtures or combinations of two or more thereof.

23. The method of claim 14 wherein the composition is selective for etching metal nitride with respect to swelling of photoresist materials.

24. The method of claim 14 wherein the organic onium hydroxide comprises one or more of tetramethylammonium hydroxide, tetraethylammonium hydroxide, tetrapropylammonium hydroxide, tetrabutylammonium hydroxide, methyltriphenylammonium hydroxide, phenyltrimethylammonium hydroxide, benzyltrimethylammonium hydroxide, methyltriethanolammonium hydroxide, tetrabutylphosphonium hydroxide, methyltriphenylphosphonium hydroxide, trihexyltetradecylphosphonium hydroxide, tributyltetradecylphosphonium hydroxide, [(CH₃)₃NCH₂CH(OH)CH₂N(CH₃)₃]²⁺[OH⁻]₂, 1-butyl-3-methylimidazolium Hydroxide, trimethylsulfonium hydroxide, trimethylsulfoxonium hydroxide, trimethyl (2,3-dihydroxypropyl) ammonium hydroxide, [(C₆H₅)CH₂N(CH₃)₂CH₂CH(OH)CH₂N(CH₃)₂CH₂CH(OH)CH₂N(CH₃)₂CH₂CH(OH)CH₂N(CH₃)₂CH₂(C₆H₅)]4+[OH⁻]₄, and [(CH₃)₃NCH₂CH(OH)CH₂OH]⁺[OH⁻], hexamethonium dihydroxide.

25. The method of claim 14 wherein the metal nitride comprises a nitride of titanium, tungsten, tantalum, hafnium, zirconium or mixtures or nitrides of alloys thereof.
